(19) United States
(12) Patent Application Publication
(10) Pub. No.: US 2002/0076906 A1
(43) Pub. Date: Jun. 20, 2002

(54) Semiconductor structure including a monocrystalline film, device including the structure, and methods of forming the structure and device

(75) Inventors: Lyndee L. Hilt, Chandler, AZ (US); Jamal Ramdani, Chandler, AZ (US)

Correspondence Address: Oblon, Spivak, McClelland, Maier & Neustadt, P.C., Fourth Floor, 1755 Jefferson Davis Highway, Arlington, VA, 22202, US

(73) Assignee: Motorola, Inc.

(21) Appl. No.: 09/740,268

(22) Filed: Dec. 18, 2000

(51) Int. Cl. H01L 21/425

(52) U.S. Cl. 438/517

(57) ABSTRACT

High quality epitaxial layers (34) of monocrystalline materials can be grown overlying monocrystalline substrates (22) such as large silicon wafers by forming a compliant substrate for growing the monocrystalline layers (34). One way to achieve the formation of a compliant substrate includes first growing an accommodating buffer layer (24) on a silicon wafer (22), growing a thin monocrystalline layer (26) of material over the buffer layer (24), and exposing the buffer layer (24) to an anneal process to form an amorphous layer (32) capped with the monocrystalline material (26). The accommodating buffer layer (24) is lattice matched to both the underlying silicon wafer (22) and the overlying monocrystalline material layer (26). In addition, formation of a compliant substrate may include utilizing surfactant enhanced epitaxy, epitaxial growth of single crystal silicon onto single crystal oxide, and epitaxial growth of Zintl phase materials.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer formed over a monocrystalline substrate.

### BACKGROUND OF THE INVENTION

Semiconductor devices often include multiple layers of conductive, insulative, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monocrystalline thin films on a foreign substrate such as silicon (Si). To achieve optimal characteristics of the various monocrystalline layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of the material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline substrate and for a process for making such a structure. In other words, there is a need for providing the formation of a monocrystalline substrate that is compliant with a high quality monocrystalline material layer so that preferably true, two-dimensional growth can be achieved for the formation of quality semiconductor structures, devices and integrated circuits, having a grown monocrystalline film of the same crystal orientation as an underlying substrate. This monocrystalline material layer may be comprised of a semiconductor material, a compound semiconductor material, and other types of material such as metals.

### BRIEF DESCRIPTION OF THE DRAWINGS

The present invention is illustrated by way of example and not limitation in the accompanying figures, in which like references indicate similar elements, and in which:

FIGS. 1-5 illustrate schematically, in cross section, device structures in accordance with various embodiments of the invention;

FIG. 6 illustrates graphically the relationship between maximum attainable film thickness and lattice mismatch between a host crystal and a grown crystalline overlayer;

FIGS. 7A-7D illustrate schematically, in cross-section, the formation of a device structure in accordance with another embodiment of the invention;

FIGS. 8A-8D illustrate a probable molecular bonding structure of the device structures illustrated in FIGS. 7A-7D;

FIGS. 9-11 illustrate schematically, in cross-section, the formation of yet another embodiment of a device structure in accordance with the invention; and

FIG. 12 illustrates a device structure in accordance with the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, an accommodating buffer layer 24 comprising a monocrystalline material, and a monocrystalline cap layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

Structure 20 may also include a template layer 30 between the accommodating buffer layer and monocrystalline cap layer 26. As will be explained more fully below, the template layer helps to initiate the growth of the monocrystalline cap layer on the accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. In accordance with one embodiment of the invention, substrate 22 is a single-domain material—e.g., Si (100) that is up to about 6° off axis toward the [011] direction, and preferably, about 4° off axis toward the [011] direction. Typical Si (100) substrates are two-domain materials, with each domain (a 2×1 domain and a 1×2 domain) rotated 90° from the other. Rotating the Si (100) substrate up to 6° toward the [011] direction creates a single domain 2×1 surface for subsequent monocrystalline growth and is thought to reduce an amount of defects that form in the subsequently grown films.

In accordance with the present invention, accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline cap layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

The material for monocrystalline cap layer 26 can be selected, as desired, for a particular structure or application. In general, as explained in more detail below, layer 26 functions a cap, which maintains its monocrystalline form when structure 20 is exposed to a heat or temperature cycling process configured to transform at least a portion of layer 24 to an amorphous structure. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. Monocrystalline cap layer 26 may also comprise other semiconductor materials such as Group IV semiconductors—e.g., Si, metals, or other materials which are used in the formation of semiconductor structures, devices and/or integrated circuits. In accordance with the present invention, both layers 24 and 26 follow the domain registry of underlying substrate 22 (e.g., the 2×1 structure of a 4° off axis Si substrate), allowing for relatively defect—free film growth of the layers.

Appropriate materials for template 30 are discussed below. Suitable template materials chemically bond to the surface of accommodating buffer layer 24 at selected sites. and provide sites for the nucleation of the epitaxial growth of monocrystalline cap layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that structure 40 includes a crystalline accommodating buffer layer 25 and an amorphous layer 27, rather than monocrystalline accommodating buffer layer 24. Layer 25 of structure 40 is a monocrystalline layer, which may include any material previously described in connection with layer 24 of structure 20, and layer 27 is an amorphous layer that may include accommodating buffer layer materials and/or substrate 22 materials. As explained in greater detail below, layers 25 and 27 are formed by exposing structure 20 to one or more heat or anneal processes to cause at least a portion of layer 24 to become amorphous. During the heating or annealing process, at least a portion of layer 24 becomes amorphous, forming layer 27. In addition, a portion of substrate 22 may mix with the accommodating buffer materials, and thus layer 27 may include materials from both substrate 22 and the accommodating buffer layer.

FIG. 3 schematically illustrates, in cross section, a portion of a semiconductor structure 50 in accordance with another exemplary embodiment of the invention. Structure 50 is similar to structure 40, except that structure 50 includes an amorphous layer 32, rather than accommodating buffer layer 25 and amorphous interface layer 27. Amorphous layer 32 may include any of the materials previously described above in connection with layer 24, and is formed by exposing either of structures 20 or 40 to a heat or anneal process sufficient to cause layers 24 or 25 to become amorphous.

Amorphous layers 27 and 32 serve to relieve strain that might otherwise remain in the monocrystalline accommodating buffer layer and monocrystalline cap layer 26 as a result of differences in the lattice constants (distance between atoms of a cell measured in the plane of the surface) of the substrate and the subsequently grown layers. Reducing the strain between the layers helps confine dislocations at the interface between the now amorphous accommodating buffer and layer 26. Thus, forming amorphous layer 27 or 32 provides a more compliant substrate for subsequent monocrystalline film growth.

In accordance with one embodiment of the present invention, cap layer 26 serves as an anneal cap during layer 27 or 32 formation and as a template for subsequent monocrystalline layer formation. Accordingly, layer 26 is preferably thick enough to provide a suitable template for subsequent layer growth (at least one monolayer) and thin enough to allow layer 26 to form as a substantially defect free monocrystalline material. Furthermore, the combination of layers 32 and 26 form a pseudomorphic layer for subsequent deposition of monocrystalline films.

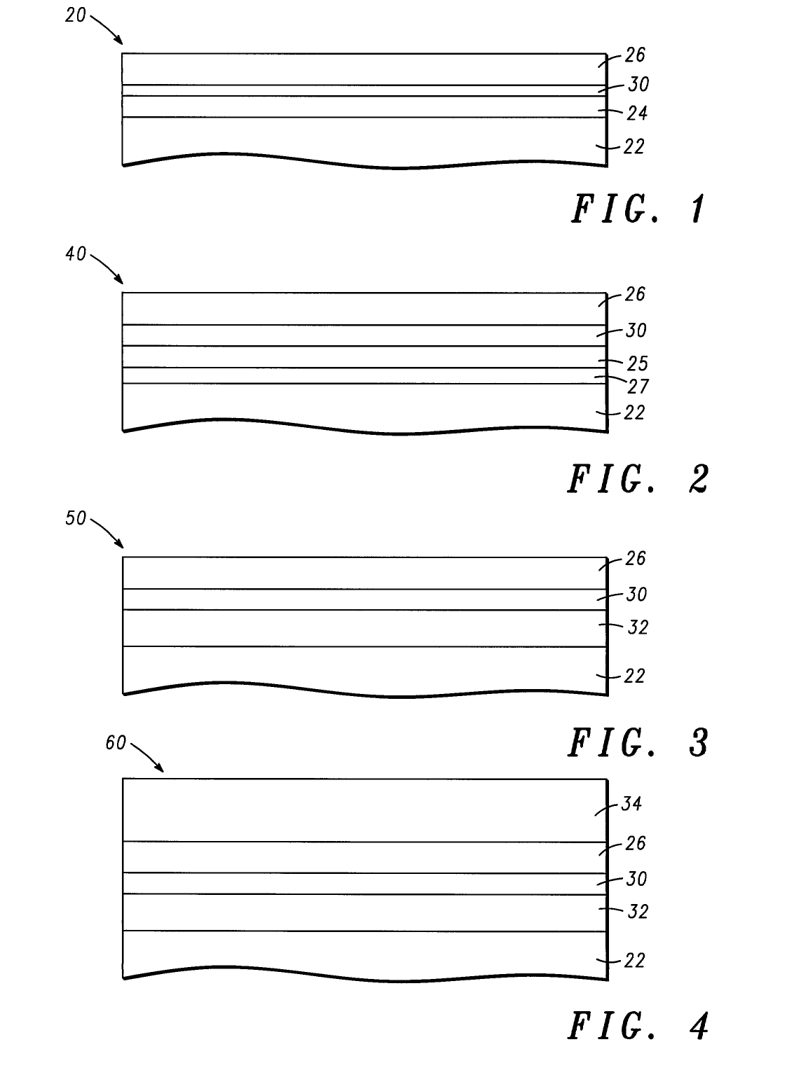

FIG. 4 schematically illustrates, in cross section, a portion of a semiconductor structure 60 in accordance with yet another exemplary embodiment of the invention. Structure 60 is similar to structure 50 of FIG. 3, except that structure 60 includes an additional layer of monocrystalline material 34. In accordance with this embodiment of the invention, layer 34 includes material suitable for forming a portion of a microelectronic device. For example, layer 34 may include monocrystalline semiconducting material, insulating material, conducting material, or a combination thereof. If layer 34 material differs from layer 26 material, structure 60 may also include a suitable template layer (not illustrated) to facilitate epitaxial growth of layer 34 over layer 26.

Layer 34 may comprise any of the materials described above in connection with layer 26. In accordance one exemplary embodiment of the invention, layer 34 includes the same material as layer 26, e.g., a compound semiconductor material such as GaAs.

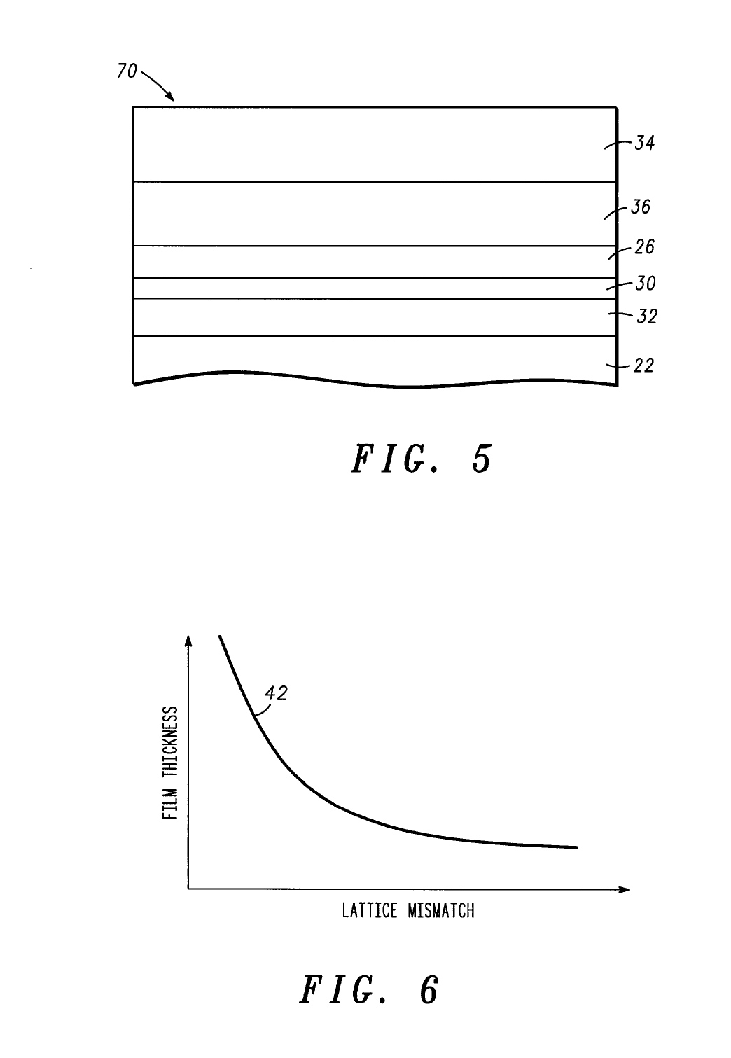

FIG. 5 schematically illustrates a semiconductor structure 70 in accordance with another embodiment of the invention. Structure 70 is similar to structure 60, except that structure 70 includes an additional buffer layer 36.

In general, layer 36 provides a transition in lattice constants between the lattice constant of cap layer 26 and a subsequently deposited layer of monocrystalline material overlying buffer layer 36. In accordance with one embodiment of the invention, the material for layer 36 is selected so that the lattice constant of layer 36 can be altered by changing the composition of layer 36, such that a bottom portion of layer 36 is lattice matched to cap layer 26 and a top portion of layer 36 is lattice matched to the subsequently applied layer of monocrystalline material.

The material for buffer monocrystalline layer 36 can be selected, as desired, for a particular structure or application. For example, the monocrystalline material of layer 36 may comprise a mixed Group IV semiconductor, where the lattice constant of the material is altered as a function of thickness of the film by varying the ratio of components in the film. In accordance with one embodiment of the invention, layer 36 comprises SiₓGe₁₋ₓ (x ranges from 0-1) where the concentration of germanium is low (i.e. 0%) near the surface of layer 26 and high (i.e. 100%) near the top of layer 36. In this case, the lower surface of layer 36 is closely lattice matched to material comprising cap layer 26, whereas the top of layer 36 is lattice matched to layer 34. Thus, structure 70 provides a suitable substrate for subsequent growth of monocrystalline material (such as compound semiconductor material) having a lattice constant that differs from the lattice constants of materials of either substrate 22 or cap layer 26.

In accordance with another embodiment of the invention, layer 26 comprises monocrystalline material that is thick enough to form the desired device. In this case, a semiconductor structure in accordance with the present invention does not include monocrystalline material layer 34.

The following non-limiting, illustrative examples illustrate various combinations of materials useful in structures 20, 40, 50, 60, and 70 in accordance with various alternative embodiments of the invention. These examples are merely illustrative, and it is not intended that the invention be limited to these illustrative examples.

### EXAMPLE 1

In accordance with one embodiment of the invention, as illustrated in FIG. 1, monocrystalline substrate 22 is a (100) silicon substrate oriented up to 6°, and preferably, about 4° off axis in the [011] direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1. The value of z is selected to obtain one or more lattice constants closely matched to corresponding lattice constants of the subsequently formed layer 26. The accommodating buffer layer can have a thickness of about 0.5 to about 100nanometers (nm) and preferably has a thickness of about 2.0-3.5 nm. In general, it is desired to have an accommodating buffer layer thick enough to isolate the compound semiconductor layer from the substrate to obtain the desired electrical and optical properties and thin enough to follow the registry of the underlying substrate, with relatively few defects.

In accordance with this embodiment of the invention, monocrystalline material layer 26 is a compound semiconductor layer of gallium arsenide (GaAs) or aluminum gallium arsenide (AlGaAs) having a thickness of about 0.5 nm to about 100 micrometers (μm) and preferably a thickness of about 2.5-3.0 nm. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, also illustrated in FIG. 1, monocrystalline substrate 22 is a silicon substrate as described above. The accommodating buffer layer is a monocrystalline oxide of strontium or barium zirconate or hafnate in a cubic or orthorhombic, having a thickness of about 2-4 nm. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 1-100 nm and preferably a thickness of about 2-4 nm. The II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22 and monocrystalline cap layer 26 can be similar to those described in example 1. As noted above, structure 40 may be formed by exposing structure 20 to an anneal or heat process such that at least a portion of the accommodating buffer layer becomes amorphous and forms layer 27.

In accordance with one embodiment of the invention, layer 27 is formed by exposed structure 20 to a rapid thermal anneal process at a temperature of about 700-900° C. for about five seconds to about 10 minutes.

### EXAMPLE 5

This example illustrates materials useful in a structure 60 as illustrated in FIG. 4. Substrate material 22, monocrystalline cap layer 26, and template layer 30 can be the same as those described above in example 1. In accordance with this example, an additional buffer layer 36 is formed above cap layer 26 and an additional layer of compound semiconductor material layer 34 is formed over layer 36. Graded layer 36, a further monocrystalline material which in this instance comprises a semiconductor material, can be, for example, a graded layer of indium gallium arsenide (InGaAs) or indium aluminum arsenide (InAlAs). In accordance with one aspect of this embodiment, graded layer 36 includes InGaAs, in which the indium composition varies from 0 to about 50%. The buffer layer preferably has a thickness of about 1-30 nm. Varying the composition of the buffer layer from GaAs to InGaAs serves to provide a lattice match between the underlying monocrystalline accommodating buffer layer material and the overlying layer of monocrystalline material which in this example is a compound semiconductor material. Such a graded layer is especially advantageous if there is a lattice mismatch between accommodating buffer layer 24 and monocrystalline material layer 34.

### EXAMPLE 6

This example provides exemplary materials useful in structure 70, as illustrated in FIG. 5. Substrate material 22, template layer 30, and monocrystalline material layer 26 may be the same as those described above in connection with example 1.

Amorphous layer 32 is an amorphous oxide layer which is suitably formed of a accommodating buffer layer materials (e.g., layer 24 materials as described above). For example, amorphous layer 32 may include Sr_{z}Ba_{1-z}TiO₃ (where z ranges from 0 to 1).

Layer 36 comprises a monocrystalline material that can be grown epitaxially over a cap layer 26. In accordance with one embodiment of the invention, layer 36 comprises ______ nm of SiₓGe₁₋ₓ, where x ranges from about one at a lower surface of layer 36 to about zero near a top surface of layer 36.

Referring again to FIGS. 1-5, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

FIG. 6 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) monocrystalline silicon wafer oriented up to about 6°, and preferably, about 4° off axis in the [011] direction and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer.

Still referring to FIGS. 1-5, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-5. The process starts by providing a monocrystalline semiconductor substrate comprising silicon or germanium. In accordance with a preferred embodiment of the invention, the semiconductor substrate is a (100) silicon wafer having a orientation about 4° off axis in the [011] direction. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline accommodating buffer material. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 850 ° C. At this temperature a solid state reaction takes place between the strontium oxide and the native silicon oxide, causing the reduction of the native silicon oxide and leaving an ordered 2×1 structure with strontium, oxygen, and silicon remaining on the substrate surface. Again, this forms a template for the subsequent growth of an ordered monocrystalline accommodating buffer layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is set at or near a minimum value to grow stochiometric strontium titanate at a growth rate of about 0.3-0.5 nm per minute. The strontium titanate grows as an ordered monocrystal with the crystalline orientation rotated by 45° with respect to the ordered 2×1 crystalline structure of the underlying substrate.

After the strontium titanate layer has been grown to the desired thickness, a template layer, which is conducive to the subsequent growth of an epitaxial layer of a desired monocrystalline material, is formed. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of strontium, 1-2 monolayers of titanium-oxygen or with 1-2 monolayers of strontium-oxygen. Following the formation of this layer, arsenic is deposited to form a Ti—As bond, a TiO—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the template layer to form a Sr—O—Ga bond, and arsenic is subsequently introduced with the gallium to form the GaAs.

Once the GaAs layer is formed, the structure is exposed to an anneal or heat process sufficient to cause at least a portion of layer 24 to become amorphous, as illustrated in FIG. 2, or all of layer 24 to become amorphous, as illustrated in FIG. 3.

The structure illustrated in FIG. 5 can be formed by the process discussed above with the addition of an additional buffer layer 36 and layer 34 deposition steps. The buffer layer is formed overlying layer 26 before the deposition of the monocrystalline material layer 34. In accordance with one embodiment of the invention, layer 26 comprises Si, layer 36 comprises SiGe, and layer 34 comprises GaAs.

If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

In accordance with one aspect of this embodiment, layer 27 is formed by exposing substrate 22, the accommodating buffer layer, and monocrystalline layer 26 to a rapid thermal anneal process with a peak temperature of about 700° C to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, radiation annealing, or “conventional” thermal annealing processes (in the proper environment) may be used to form layer 27. When conventional thermal annealing is employed to form layer 27, an overpressure of one or more constituents of layer 26 may be required to prevent degradation of layer 26 during the anneal process. For example, when layer 26 includes GaAs, the anneal environment preferably includes an overpressure of arsenic to mitigate degradation of layer 26.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, peroskite oxides such as alkaline earth metal tinbased perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and other materials can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be topped with a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be topped with a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the terminating material to form a template for the deposition of a monocrystalline material layer comprising compound semiconductors such as indium gallium arsenide, indium aluminum arsenide, or indium phosphide.

The formation of a device structure in accordance with another embodiment of the invention is illustrated schematically in cross-section in FIGS. 7A-7D. Like the previously described embodiments referred to in FIGS. 1-5, this embodiment of the invention involves the process of forming a compliant substrate utilizing the epitaxial growth of single crystal layers, such as the formation of accommodating buffer layer 24 previously described with reference to FIG. 1 and the formation of a template layer 30. However, the embodiment illustrated in FIGS. 7A-7D utilizes a template that includes a surfactant to facilitate layer-by-layer monocrystalline material growth.

Turning now to FIG. 7A, an accommodating buffer layer 54, which is preferably a monocrystalline crystal oxide layer, is formed on a substrate 52 using the method described above. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference to layer 24 in FIG. 1.

Layer 54 is grown with a strontium terminated surface represented in FIG. 7A by hatched line 55 which is followed by the addition of a template layer 58 which includes a surfactant layer 61 and terminating layer 63 as illustrated in FIGS. 7B and 7C. Surfactant layer 61 may comprise, but is not limited to, elements such as Al, In and Ga, but will be dependent upon the composition of layer 54 and the overlying layer of monocrystalline material for optimal results. In one exemplary embodiment, aluminum is used for surfactant layer 61 and functions to modify the surface and surface energy of layer 54. Preferably, surfactant layer 61 is epitaxially grown, to a thickness of one to two monolayers, over layer 54 as illustrated in FIG. 7B by way of MBE, although other epitaxial processes may also be performed including CVD, MOCVD, MEE, ALE, PVD, CSD, PLD, or the like.

Surfactant layer 61 is then exposed to a halogen such as arsenic, for example, to form terminating layer 63 as illustrated in FIG. 7C. Surfactant layer 61 may be exposed to a number of materials to create terminating layer 63 such as elements which include, but are not limited to, As, P, Sb and N. Surfactant layer 61 and terminating layer 63 combine to form template layer 58.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 7D. Once the GaAs layer is formed, the structure may be exposed to a heat or anneal process to cause a portion of layer 54 to become amorphous or all of layer 54 to become amorphous. Then, subsequent layers of monocrystalline material may be deposited over layer 66.

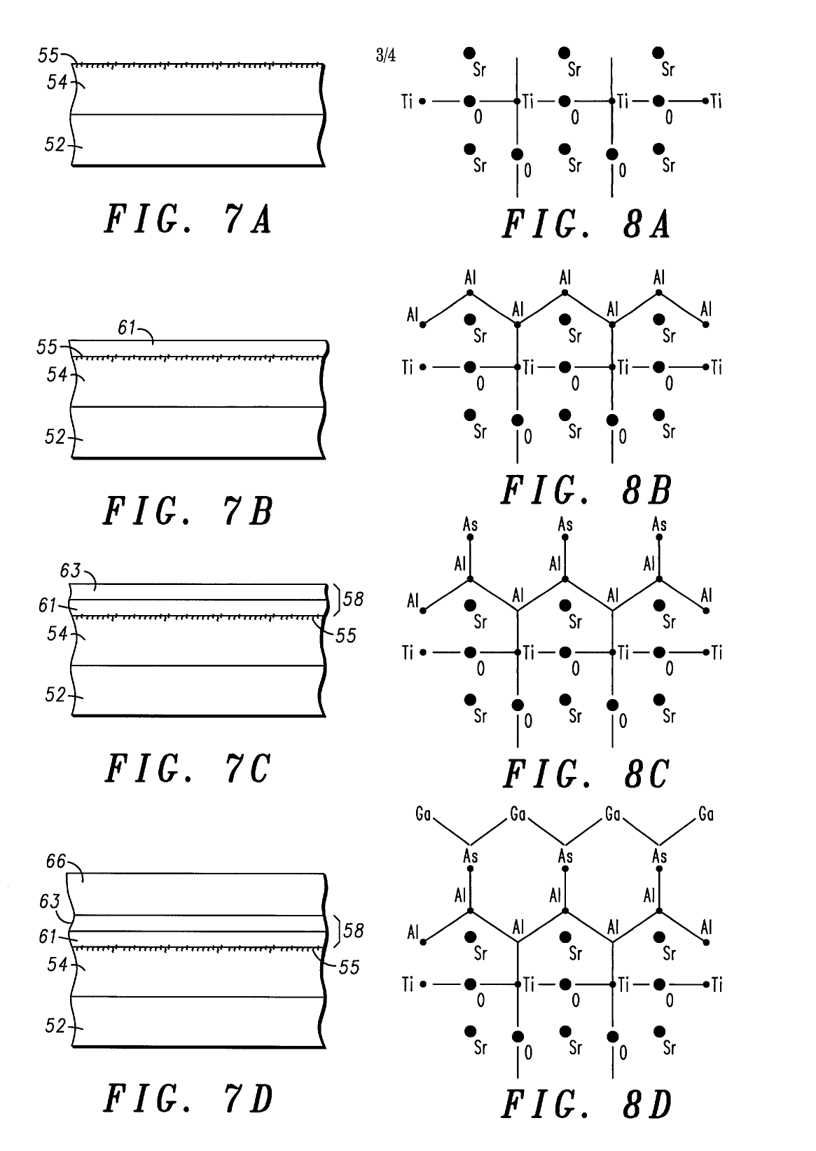

FIGS. 8A-8D illustrate possible molecular bond structures for a specific example of a compound semiconductor structure formed in accordance with the embodiment of the invention illustrated in FIGS. 7A-7D. More specifically, FIGS. 8A-8D illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over substrate layer 52, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{Substrate}+δ_{GaAs})

where the surface energy of the monocrystalline oxide layer 54 must be greater than the surface energy of substrate 52 added to the surface energy of GaAs layer 66. Since it is impracticable to satisfy this equation absent a surfactant, a surfactant containing template was used, as described above with reference to FIGS. 7B-7D, to increase the surface energy of the monocrystalline oxide layer 54 and also to shift the crystalline structure of the template to a diamond-like structure that is in compliance with the original GaAs layer.

FIG. 8A illustrates the molecular bond structure of a strontium terminated surface of a strontium titanate monocrystalline oxide layer. An aluminum surfactant layer is deposited on top of the strontium terminated surface and bonds with that surface as illustrated in FIG. 8B, which reacts to form a terminating layer comprising a monolayer of Al₂Sr having the molecular bond structure illustrated in FIG. 8B which forms a diamond-like structure with an sp³ hybrid terminated surface that is compliant with compound semiconductors such as GaAs. The structure is then exposed to As to form a layer of AlAs as shown in FIG. 8C. GaAs is then deposited to complete the molecular bond structure illustrated in FIG. 8D which has been obtained by 2D growth. The GaAs can be grown to any thickness for forming other semiconductor structures, devices, or integrated circuits. Alkaline earth metals such as those in Group IIA are those elements preferably used to form the terminating surface of the monocrystalline oxide layer 24 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising germanium, for example, to form high efficiency photocells.

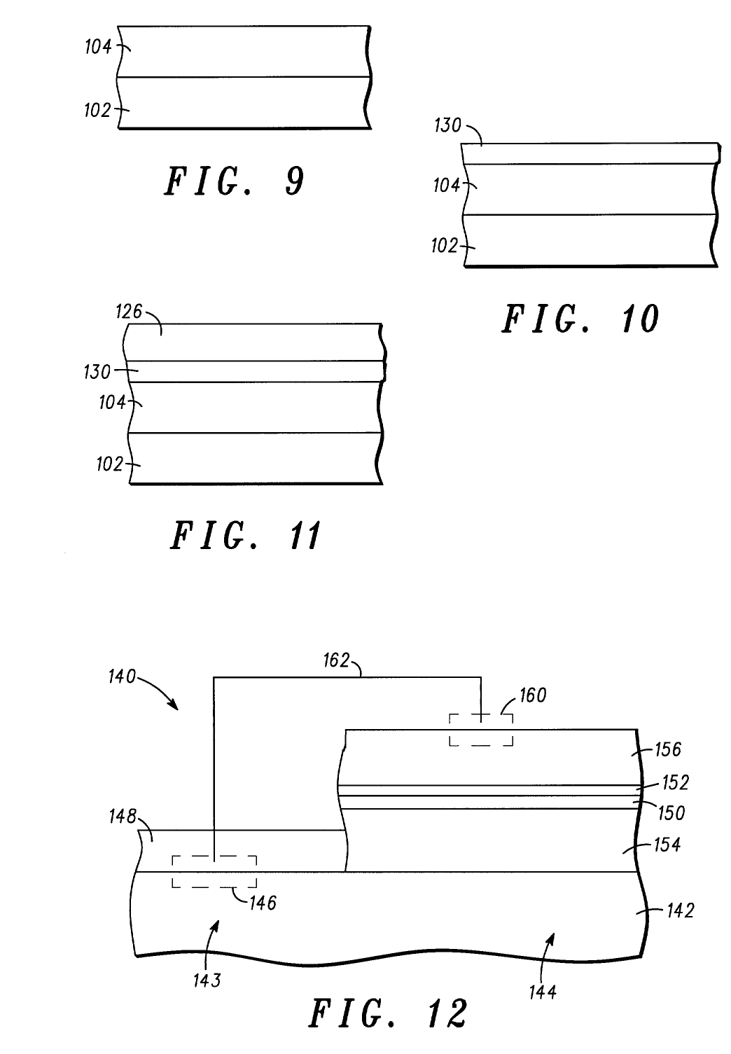

FIGS. 9-11 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers, thereby allowing for two dimensional layer by layer growth.

The structure illustrated in FIG. 9 includes a monocrystalline substrate 102 and an accommodating buffer layer 104 as previously described with reference to FIG. 1. A template layer 130 is deposited over accommodating buffer layer 104 as illustrated in FIG. 12 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of about one monolayer. Template layer 130 functions as a “soft” layer with non-directional bonding and high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

A monocrystalline material layer 126 is epitaxially grown over template layer 130 to achieve the final structure illustrated in FIG. 11. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer, thereby making the device tunable for specific applications which include the monolithic integration of III-V and Si devices and the monolithic integration of high-k dielectric materials for CMOS technology.

FIG. 12 illustrates schematically, in cross section, a device structure 140 in accordance with a further embodiment of the invention. Device structure 140 includes a monocrystalline semiconductor substrate 142, preferably a monocrystalline silicon wafer. Monocrystalline semiconductor substrate 142 includes two regions, 143 and 144. An electrical semiconductor component generally indicated by the dashed line 146 is formed, at least partially, in region 143. Electrical component 146 can be a resistor, a capacitor, an active semiconductor component such as a diode or a transistor or an integrated circuit such as a CMOS integrated circuit. For example, electrical semiconductor component 146 can be a CMOS integrated circuit configured to perform digital signal processing or another function for which silicon integrated circuits are well suited. The electrical semiconductor component in region 143 can be formed by conventional semiconductor processing as well known and widely practiced in the semiconductor industry. A layer of insulating material 148 such as a layer of silicon dioxide or the like may overlie electrical semiconductor component 146.

Insulating material 148 and any other layers that may have been formed or deposited during the processing of semiconductor component 146 in region 143 are removed from the surface of region 144 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 144 and is reacted with the oxidized surface to form a first template layer (not shown). In accordance with one embodiment of the invention a monocrystalline oxide layer is formed overlying the template layer by a process of molecular beam epitaxy. Reactants including barium, titanium and oxygen are deposited onto the template layer to form the monocrystalline oxide layer. During the deposition, the partial pressure of oxygen is kept near the minimum necessary to fully react with the barium and titanium to form the monocrystalline barium titanate layer.

In accordance with an embodiment of the invention, the step of depositing the monocrystalline oxide layer is terminated by depositing a layer 150, which can be 1-10 monolayers of titanium, barium, strontium, barium and oxygen, titanium and oxygen, or strontium and oxygen. A cap layer 152 of a monocrystalline semiconductor material is then deposited overlying the second template layer by a process of molecular beam epitaxy.

In accordance with one aspect of the present embodiment, after layer 152 formation, the monocrystalline titanate layer is exposed to an anneal process such that the titanate layer forms an amorphous oxide layer 154. A monocrystalline material layer 156 is then epitaxially grown over layer 152, using the techniques described above in connection with layer 34 of FIG. 4.

In accordance with a further embodiment of the invention, a semiconductor component, generally indicated by a dashed line 160 is formed, at least partially, in compound semiconductor layer 156. Semiconductor component 160 can be formed by processing steps conventionally used in the fabrication of gallium arsenide or other III-V compound semiconductor material devices. Semiconductor component 160 can be any active or passive component, and preferably is a semiconductor laser, an electromagnetic radiation (e.g., light—infra red to ultra violet radiation) emitting device, an electromagnetic radiation detector such as a photodetector, a heterojunction bipolar transistor (HBT), a high frequency MESFET, or another component that utilizes and takes advantage of the physical properties of compound semiconductor materials. A metallic conductor schematically indicated by the line 162 can be formed to electrically couple device 146 and device 160, thus implementing an integrated device that includes at least one component formed in the silicon substrate and one device formed in the monocrystalline material layer. Although illustrative structure 140 has been described as a structure formed on a silicon substrate 142 and having a barium (or strontium) titanate layer and a gallium arsenide layer 156, similar devices can be fabricated using other monocrystalline substrates, oxide layers and other monocrystalline material layers as described elsewhere in this disclosure.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g., conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a single-domain monocrystalline substrate;
an accommodating buffer layer formed over the substrate; and
a monocrystalline cap layer formed over the accommodating buffer layer.

2. The semiconductor structure of claim 1, wherein the accommodating buffer layer is monocrystalline.

3. The semiconductor structure of claim 1, wherein the accommodating buffer layer includes an amorphous region.

4. The semiconductor structure of claim 1, wherein the accommodating buffer layer is amorphous.

5. The semiconductor structure of claim 1, further comprising a layer of monocrystalline material formed over the cap layer.

6. The semiconductor structure of claim 1, further comprising a template layer formed between the accommodating buffer layer and the cap layer.

7. The semiconductor structure of claim 1, further comprising a template layer between the substrate and the accommodating buffer layer.

8. The semiconductor structure of claim 1, wherein the accommodating buffer layer comprises a monocrystalline oxide.

9. The semiconductor structure of claim 1, wherein the accommodating buffer layer comprises a monocrystalline nitride.

10. The semiconductor structure of claim 1, wherein the accommodating buffer layer comprises SrₓBa₁₋ₓTiO₃, where x ranges from 0 to 1.

11. The semiconductor structure of claim 1, wherein the substrate comprises (100) silicon, with a surface having a crystal orientation about 4° off axis in the [011] direction.

12. The semiconductor structure of claim 1, wherein the cap layer comprises gallium arsenide.

13. The structure of claim 1, further comprising a buffer layer overlying the cap layer.

14. A microelectronic device formed using the structure of claim 1.

15. A process for fabricating a semiconductor structure comprising the steps of:
providing a single-domain monocrystalline substrate;
epitaxially growing a monocrystalline accommodating buffer layer over the substrate; and
epitaxially growing a cap layer over the accommodating buffer layer.

16. The process according to claim 15, further comprising the step of annealing the accommodating buffer layer to cause the buffer layer to change from monocrystalline to at least partially amorphous.

17. The process according to claim 16, wherein the step of annealing comprises the step of rapid thermal annealing.

18. The process according to claim 17, wherein the step of rapid thermal annealing comprises rapid thermal annealing at a temperature between about 700 ° C. to about 1000° C.

19. The process according to claim 15, further comprising the step of forming a template on the substrate.

20. The process according to claim 15, further comprising the step of forming a template on the accommodating buffer layer.

21. The process according to claim 15, further comprising the step of forming a additional monocrystalline layer overlying the cap layer.

22. The process according to claim 21, further comprising the step of forming a microelectronic component using the additional monocrystalline layer.

23. The process according to claim 15, further comprising the step of forming a microelectronic component using the substrate.

24. The process according to claim 15, further comprising forming a buffer layer overlying the cap layer.

25. A microelectronic device formed according to the method of claim 15.

26. A semiconductor device comprising:
a single-domain silicon substrate;
a first portion, the first portion including a microelectronic component formed using the single-domain silicon substrate; and
a second portion, the second portion including a monocrystalline film formed above the single-domain silicon substrate, having a microelectronic component formed using the monocrystalline film.

27. The semiconductor device of claim 26, further comprising an accommodating buffer layer interposed between the single-domain silicon substrate and the monocrystalline film.

28. The semiconductor device of claim 27, wherein at least a portion of the accommodating buffer layer is amorphous.

29. The semiconductor device of claim 27, wherein the accommodating buffer layer is monocrystalline.
